(19) United States
(12) Patent Application Publication
(10) Pub. No.: US 2023/0357009 A1
(43) Pub. Date: Nov. 9, 2023

(54) INTERFACIAL FERROELECTRICITY BY VAN DER WAALS SLIDING

(71) Applicant: RAMOT AT TEL-AVIV UNIVERSITY LTD., Tel Aviv (IL)

(72) Inventor: Moshe BEN SHALOM, Tel Aviv (IL)

(21) Appl. No.: 18/246,763

(22) PCT Filed: Sep. 26, 2021
(86) PCT No.: PCT/IL2021/051166

§ 371 Date: Mar. 27, 2023

Related U.S. Application Data
(60) Provisional application No. 63/083,947, filed on Sep. 27, 2020.

(51) Int. Cl. C01B 21/064

(52) U.S. Cl. CPC C01B 21/0648; C01P 2002/20; C01P 2002/76; C01P 2002/78; C01P 2006/40; C01P 2006/42; C01P 2002/77; C01P 2004/01; B82Y 10/00

(57) ABSTRACT

The technology subject of the present application concerns methods and systems for manufacturing and producing stable polarized or ferroelectric layered materials.

### FIELD OF THE INVENTION

The present invention is directed to methods and systems for inducing ferroelectric properties in a hexagonal diatomic layered material.

### BACKGROUND OF THE INVENTION

The ability to locally switch a confined electrical polarization is a key requirement in modern technologies, where storing and retrieving a large volume of information is vital. Today, after decades of intense research, it is possible to squeeze a tera (10¹²) of polarized islands in a cm² chip composed of high-quality three-dimensional (3D) crystals. The need to further reduce the dimensions of individually polarized domains, however, from the ˜100 nm² scale towards the atomic scale is rising. The main challenges involve long-range dipole interactions which tend to couple the individual domain polarization orientations. Likewise, surface effects and external strains that are difficult to control become dominant once the surface-to-volume ratio increases. Venues to overcome the abovementioned difficulties become straightforward when considering 2D crystals, in particular, in layered materials such as hexagonal-boron-nitride (h-BN) and transition-metal-dichalcogenides (TMD), where the bulk volume can be reduced to the ultimate atomic-thickness limit whereas the crystalline surface remains intact.

### SUMMARY OF THE INVENTION

It is still rare to find a spontaneous net electric polarization in 2D that is sufficiently large to read and write under ambient conditions. In common systems such as hexagonal-boron-nitride (h-BN) and transition-metal-dichalcogenides (TMD) crystals, polarization is eliminated by a centrosymmetric van der Waals (vdW) structure which is lower in energy than other stacking configurations. Hence, in such crystals, the lattice stacking structure of these materials is such that they do not exhibit polarization. The inventors of the technology disclosed herein have been able to develop a novel methodology which enables induction of ferroelectricity in diatomic hexagonal structures, at room temperature.

As used herein, the term ‘crystal’ is used alongside with ‘material’, both referring to the diatomic hexagonal layered material induced with polarization or ferroelectric properties.

Six different high symmetry stacking configurations of bilayer h-BN or hexagonal TMDs are possible. The six configurations are shown in FIG. 1A. The stacking configurations are divided into two groups termed “parallel” and “anti-parallel” twist orientations; wherein within each group a relative lateral shift by one interatomic distance switches the stacking configuration in a cyclic manner. Typically, the crystal grows in the optimal anti-parallel (AA′) configuration with full overlap between nitrogen (boron) atoms of one layer and boron (nitrogen) atoms of the adjacent layer. In the parallel twist-orientation, however, the fully eclipsed configuration (AA) is unstable since it forces pairs of bulky nitrogen atoms atop each other. This results in increased steric repulsion. Instead, a lateral interlayer shift occurs to a metastable AB stacking with only half of the atoms overlapping, whereas the other half face empty centers of the hexagons in the opposite layer. It is to be noted that the AB and BA stacking form equivalent lattice structures (only flipped), and that all depicted anti-parallel configurations (AA′, AB1′, AB2′) are symmetric under spatial inversion.

To explore the different configurations, two exfoliated h-BN flakes were artificially stamped on top of each other, each comprising a few AA′ stacked layers, with a minute twist-angle between the otherwise parallel interfacial layers. The small twist imposes interlayer translations that evolve continuously and form a Moiré pattern owing to the underlying crystal periodicity (FIG. 1B). In this rigid lattice picture, the three nearly commensurate stacking configurations (AB, BA and AA) appear at adjacent positions in space. Notably, this picture breaks for a sufficiently small twist angle as a result of structural relaxation processes as shown by molecular dynamics calculation based on dedicated interlayer potentials (FIG. 1C). Instead, the system divides into large domains of reconstructed commensurate AB and BA stackings separated by sharp incommensurate domain walls that accommodate the global twist (see FIG. 4A,B). Notably, near the center of the extended commensurate domains, perfectly aligned configurations are obtained with no interlayer twist. In experiments conducted by the inventor of the present invention, a topographic step was introduced at the interface between the flakes. A step thickness of an odd number of layers guarantees anti-parallel stacking (AA′, AB1′ or AB2′) on one side, and parallel stacking (AA, AB or BA) on its other side (FIG. 1D). Thus, one can compare all possible configurations at adjacent locations in space.

To measure variations in the electrical potential, V_{KP}, at surface regions of different stacking configurations, an h-BN sandwich was placed on a conducting substrate (graphite or gold), and scanned by an atomic force microscope (AFM) operated in a Kelvin probe mode (KPFM), FIG. 2A. The potential map above the various stacking configurations is shown in FIG. 2B. Clear domains (black and white) of constant VKP, extending over areas of several μm², were observed, which are separated by narrow domain-walls. Gray areas of average potential are observed above: (i) positions where only one h-BN flake exists (outside the dashed yellow line); (ii) above two flakes but beyond the topographic step marked by dashed line in FIG. 2B (and topography map FIG. 5) as expected; and (iii) beyond topographic folds that can further modify the interlayer twist angle (dashed line). These findings confirm that white and black domains correspond to AB and BA interfacial stacking that host a permanent out-of-plane electric polarization. Such polarization is not observed at the other side of the step, where centrosymmetric AA′, AB1′ AB2′ configurations are obtained, or at the AA configuration expected at domain-wall crossings (see dots in FIG. 1C). Sufficiently far from the domain-walls a constant potential is observed, allowing measuring of the potential difference between the AB and BA domains as shown in FIG. 2C. Whereas a KPFM measurement nullifying the tip response at the electric bias frequency gave an underestimated potential difference because of averaging contributions from the tip's cantilever, more quantitative measurements obtained through sideband tip excitations yielded ΔV_{KP} values ranging between 210 and 230 mV for both closed-loop scans and local open-loop measurements.

It is noted that similar values for ΔV_{KP} were obtained for several samples (FIG. 5), regardless of the substrate identity (Si, graphite, or gold), the type and height of the AFM tip during the scan, and the thickness of the top h-BN flake (for flakes thicker than 1 nm). These findings confirm that ΔV_{KP} is an independent measure of the intrinsic polarization of the system that, in turn, is confined within a few interfacial layers.

While the force field calculations for slightly twisted bilayer h-BN show a uniform triangular lattice of alternating AB and BA stacked domains (FIG. 1C), in the experiment large variations were observed in their lateral dimensions and shape. This indicates minute deviations in the local twist, which are unavoidable in the case of small twist angles. Specifically, the ˜1 μm² domains in the left part of FIG. 2B correspond to a global twist of less than 0.01 degree. One may also note that any external perturbation to the structure, caused either by transferring it to a polymer, heating, or directly pressing it with the AFM tip, usually resulted in a further increase in domain size. In a few cases, high-temperature annealing resulted in a global reorientation to a single domain flake, many micrometers in dimensions. This behavior confirms the metastable nature of the AB/BA stacking mode, as well as the possible superlubric nature of the interface. On the other extreme, much smaller domains are observed in the top right-hand section of FIG. 2B. The smallest triangle edge that could be identified over many similar flakes was 60 nm in length, which corresponds to a twist-angle of 0.24° . It may therefore be concluded that below this angle atomic reconstruction to create untwisted domains is energetically favored. Naturally, this constitutes a lower bound on the maximal angle for domain formation as smaller domains below the experimental resolution may form at larger twist angles.

To trace the microscopic origin of the measured polarization, a set of density functional theory (DFT) calculations were applied on finite bilayer and quad-layer h-BN flakes. For the finite bilayer calculations, two model systems were constructed, where hydrogen passivated h-BN flakes of eithe r 1 nm² or 3 nm² surface area are stacked in the AB stacking mode (see FIG. 6). The calculated polarizations per unit area were 0.55, 0.45 Debye/nm², respectively (see black triangles in FIG. 2D), pointing perpendicular to the interface. The fact that the calculated polarization values for the two finite flakes are similar indicates that edge effects have a relatively small contribution. This is further supported by the smaller effective charges residing on the edge atoms in both bilayer systems (see FIG. 6). To model a finite four-layer system, two AA′ stacked layers were added at the two sides of the AB stacked interface. To avoid excessive computational burden, this calculation was limited to a surface area of 1 nm². The resulting polarization obtained was 0.91 Debye/nm² (see FIG. 2D, squares), larger than that obtained for the bilayers. This may be attributed to remnant edge contributions in the finite-size structure. Comparison with the experimental observations can be performed by adopting a parallel plate capacitor model that translates the measured potential drop, ΔV_{KP}, to the effective system polarization via P_{z}=ΔV_{KP}/2 ε₀εᵣA, where A is the contact surface area and ε₀ and εᵣ=3 are the vacuum permittivity and the relative normal permittivity of single-layered h-BN, respectively. The resulting polarization per unit area is 0.66 Debye/nm² (star in FIG. 2D), in reasonable quantitative agreement with the calculated values.

It is instructive to further translate the measured potential difference into intra-layer displacements in a simplistic point-like charges model (see Δd in FIG. 1D), where each atom is allowed to displace from its layer's basal plane in the vertical direction. Note that using the lattice site density of n=37 nm⁻², and the on-site charge value, q˜e/2, for single-layered h-BN, the measured ΔV_{KP} gives out-of-plane atomic displacement of the order of Δd=ΔV_{KP}ε₀εᵣ/4nq˜2×10⁻³ Å, which is significantly smaller than the inter-lattice (1.44 Å) and interlayer (3.30 Å) spacing. This implies that polarization is determined by a delicate competition between the various interlayer interaction components and charge redistribution. Intuitively, it is expected the vdW attraction to vertically compress the non-overlapping interfacial sites (diagonal dashed ellipse in FIG. 1D) closer together than the overlapping sites (vertical dashed ellipse in FIG. 1D) which are more prone to Pauli repulsion. This direction of motion, for example, reduces the average interlayer separation and favors Bernal (AB like) stacking in graphite over the AA configuration. In h-BN, however, the ionic nature of the two lattice sites matters, making the fully eclipsed AA′ stacking more stable. Hence, imposing a polar AB interface, may favor overlapping sites of opposite charges to come closer together than the non-overlapping pairs and the polarization to point in the opposite direction.

To quantify these arguments, a reduced classical bilayer model was presented that captures the intricate balance between Pauli, vdW, and Coulomb interatomic interactions at different stacking modes. In this model, the interfacial energy

$$E = \frac{1}{2} {\sum }_{i , j} [ 4 ε ( {( \frac{σ}{{r}_{i j}} )}^{12} - {( \frac{σ}{{r}_{i j}} )}^{6} ) + \frac{{q}_{i} {q}_{j}}{{r}_{i j}} ]$$

includes a Lennard-Jones (LJ) potential characterized by the cohesive energy, ε, and the interlayer spacing scale σ, and Coulomb interactions between the dimensionless partial atomic charges on the boron and nitrogen sites q=±qᵢ/e. Although neglecting any charge transfer processes between the layers that are explicitly taken into account in the DFT calculations, this model captures both the magnitude and orientation of the polarization by adjusting the ratio between ε and Coulomb scales∝q²/σ (see FIG. 7). It should be noted that the detailed DFT calculations indicate that in bilayer h-BN the net polarization is oriented as marked by the arrows in FIG. 1D.

The emergence of permanent polarization observed in separated domains, which dimensions can be tuned by the twist-angle, each exhibiting a distinct and stable potential, opens the door for novel applications. It is noteworthy that polarization inversion can be achieved by reversible switching between AB and BA configurations which, in turn, can be realized by relative lateral translation by one atomic spacing (1.44 Å) as illustrated in FIG. 1A. In the h-BN interface, the polar switching calls for a preferred up or down orientation which can be predetermined by the user. To obtain such a spatially resolved control, a biased tip was scanned above an individual domain to induce a local electric field normal to the interface. The polarization images before and after the biased scans are presented in FIG. 3. A redistribution of domain-walls to orient the local polarization with the electric field under the biased tip was observed. For example, after scanning a negatively biased tip above the region marked by the square, a large white domain due to the motion of the walls was observed. A successive scan by a positively biased tip resulted in practically complete domain polarization flipping. Hence, by selecting negative or positive bias to the tip it is possible to determine the polarization orientation of the underlying domain. It should be noted that domain-wall motion was observed for electric field values exceeding ˜0.3 V/nm, and when operating the biased scan in a pin-point mode. Similar switching behavior was attained above different domains within the same interface and for several measured structures (see FIG. 8).

The results therefore demonstrate that the broken symmetry at the interface of parallel-stacked h-BN flakes gives rise to an out-of-plane two-dimensional polarization confined within a few interfacial layers that can be locally detected and controlled. While the h-BN system, with its only two different light atoms, offers a comfortable experimental and computational testbed and allows for intuitive interpretations, similar phenomena is expected to occur in other more complex bi-atomic vdW crystals, such as various TMDs. Notably, the origin of the polarization and the inversion mechanism developed herein are fundamentally different from the common deformations of tightly-bonded atoms in non-centrosymmetric 3D bulk crystals. The “slidetronics” switching involves lateral domain-wall motion in a weakly-coupled interface under ambient conditions. The sensitivity of the system to the delicate interplay between van der Waals attraction, Pauli repulsion, Coulomb interactions and charge redistribution implies that external stimuli such as pressure, temperature, and/or electric fields may be used to control the polarization, thus offering many opportunities for future research.

Thus, in a first of its aspects, the invention provides a process for inducing polarization in a stacked multilayered diatomic hexagonal material, the process comprising orienting any two stacked layers of a diatomic hexagonal material into a stacked parallel lattice orientation to induce internal interfacial electric field normal to the layers plane at an interface between the two stacked material layers. In other words, by achieving parallel lattice orientation, internal interfacial electric field normal to the layer plane of the crystal may be achieved.

As used herein, orientation of any two stacked layers may be achievable by a variety of methodologies, as disclosed hereinbelow. In some embodiments, orientation is achieved by positioning two or more layers or flakes of the material atop of each other in a parallel lattice orientation as disclosed herein. Reference to “any two stacked material layers” is to any two material layers that are immediately on top of each other, not separated by a further layer. For example, in a multilayered structure comprising three material layers, a, b and c, the expression refers to layers a and b or layers b and c. Polarization is measurable at an interface between any two layers a and b, or b and c, in the specific example, of the multilayered material, as an internal interfacial electric field normal to the layer plane of the crystal. In a three-layered material, two layer interfaces are present. Polarization orientation in each interface may be the same or different.

The invention also provides a process for inducing polarization in a stacked multilayered diatomic hexagonal material, the process comprising layering two or more flakes of a diatomic hexagonal material such that a stacked multilayered material is obtained wherein each layer in the multilayered material is in a parallel lattice orientation, said stacked multilayered material exhibiting polarization at an interface between any two material layers in said multilayered material.

In an exemplary case of a method for manufacturing a stable h-BN ferroelectric crystal, a process according to the invention may comprise:
providing a hexagonal-boron-nitride (h-BN) crystal or material;
separating (or exfoliating) layers making up the h-BN crystal or material into septate layers;
twisting at least one of the separated layers, such that the layers form an interface having a metastable non-centrosymmetric parallel orientation,
thereby creating a stable ferroelectric crystal that transmits ferroelectricity.

This process may be employed on any diatomic hexagonal multilayered or layered material as disclosed herein.

In some embodiments, the process of inducing polarization comprises layering two or more flakes of a diatomic hexagonal material such that a stacked multilayered material is obtained wherein each layer in the multilayered material is in a parallel lattice orientation.

In some embodiments, the process comprising depositing a layer of a diatomic hexagonal material on top a layer of same diatomic hexagonal material such that a stacked multilayered material is obtained wherein each layer in the multilayered material is in a parallel lattice orientation.

In some embodiments, the process comprising
providing a diatomic hexagonal multilayered crystal or material,
separating layers making up the crystal or material into separate layers, and
stacking at least one of the separated layers on top of another, such that an internal interfacial electric field normal to the layers plane of the material is formed at an interface between the two stacked material layers.

In other embodiments, the process comprising
providing two or more flakes of a diatomic hexagonal material;
stacking the two or more flakes into a multilayered material, wherein each layer in the multilayered material is in a parallel lattice orientation.

In some embodiments, the two or more flakes are obtained from exfoliating layers of a diatomic hexagonal multilayered crystal or material.

In some embodiments, the number of layers in the multilayered material is at least two.

In some embodiments, the number of layers in the multilayered material is two or three or more.

In some embodiments, the number of polarization states is equal to the number of internal interfaces between stacked layers in the multilayered material.

In some embodiments, the number of polarization states is one, or is at least two.

In some embodiments, the process is for obtaining a polarized diatomic hexagonal multilayered material having one or more same or different internal interfacial polarized states.

In other embodiments, the process is for obtaining a polarized diatomic hexagonal multilayered material having two or more same or different internal interfacial polarized states.

Non-limiting examples of diatomic hexagonal (multi) layered materials which can be used in accordance with aspects and embodiments of the invention include hexagonal-boron-nitride (h-BN), transition-metal-dichalcogenides (TMD), hexagonal-aluminum-nitride (h-AlN), hexagonal-zinc-oxide (h-ZnO), hexagonal-gallium-nitride (h-GaN), etc.

Hexagonal boron nitride, h-BN, is a ceramic material known for its high thermal conductivity, inertness, and tribological properties that render it interesting in a variety of applications. The material also finds its unique applications in polymer composites for high temperature applications and sp3 bonding in extreme temperature and compression conditions. The structural texture of h-BN is a layered structure, wherein the boron atoms and atoms of nitrogen are bound strongly due to covalent bonds present in-plane and van der Waals forces that hold the layer together. Due to it is thermal conductivity, h-BN is fascinating for various electronic applications. h-BN may possibly be used as filler material which insulates electricity for thermal radiators, polymer or ceramic composites, UV emitters and field emitters.

Transition-metal-dichalcogenides (TMD) are 2D materials exhibiting unique electrical, mechanical, and optical properties and are therefore of virtually unlimited potential in various fields, including electronic, optoelectronic, sensing, and energy storage applications. Non-limiting examples of these layered materials include MoS₂, WS₂, MoSe₂ and WSe₂.

Thus, in some embodiments, the diatomic hexagonal layered material is selected from h-BN, TMD such as MoS₂, WS₂, MoSe₂ and WSe₂ and others.

Diatomic hexagonal layered materials which may be used according to the invention are generally 2D materials having hexagonal lattice with three-fold symmetry and which permits minor plane symmetry and/or inversion symmetry. The materials are provided as exfoliated layers or alternatively in a grown layered form, for example by chemical vapor deposition (CVD) or by any similar growth method of thin layers, which can be assembled into a stack in a parallel lattice orientation of the individual layers, as disclosed herein. The thickness of the stack can be as thin as two layers only. Thicker stacks with more than two layers exhibit a larger polarization that depends on the number of parallel interfaces as calculated in FIG. 9, and measured in FIG. 10 for two adjacent interfaces in a stack of three parallel TMD layers. As shown in the figure, the magnitude of the polarization of two interfaces is twice the magnitude of the single interface. This observation validates the calculation for multi-layers stacks in FIG. 9. The linear enhancement of the polarization with the number of interfaces is owing to the highly confined interfacial polarization which is not affected by depolarization effects at the other side of the layer towards the surface of the structure. As shown in FIG. 10, multi-stack structures with N parallel layers can be used in N multi-polarization states rather than the only two up/down states in common ferroelectric devices.

In other words, the magnitude of polarization, as known in the art, of a multilayered stack structure of the invention is thus dependent on the number of layer interfaces present in the structure such that the value of the magnitude may be calculated or determined by determining the magnitude of polarization of a single interface and multiplying said value by the number of interfaces in the structure. In some embodiments, the polarization magnitude of a structure of the invention is the polarization magnitude of a single layer interface multiplied by the number of interfaces in the structure. Depolarization effects in a structure of the invention are minimized to the extent that the linear enhancement of the polarization may be predicted based on a measurable polarization for a single interface.

Thus, in some embodiments, in a material or a crystal having three or more material layers, the magnitude of polarization of the material is equal to a polarization measured or determined for a single interface between two stacked layers multiplied by the number of layer interfaces.

In some embodiments, the material or crystal may therefore be characterized by a linear enhancement of polarization, wherein the magnitude of polarization being dependent on the number of interfaces between any two stacked layers. The material or crystal may also be characterized by diminished depolarization surface effects.

In some embodiments, the number of material layers is three or more, each interface between two layers having a polarization orientation that is same or different to a polarization orientation present at an interface between any two other layers of the multilayered material.

The invention also provides a polarized diatomic hexagonal multilayered material or crystal, the material comprising two or more material layers oriented in a parallel orientation to each other, wherein each two stacked layers exhibiting polarization.

Also provided is a diatomic hexagonal multilayered material, the material comprising two or more material layers oriented in a parallel lattice orientation to each other, exhibiting or having internal interfacial electric field normal to the layers plane

In some embodiments, the material or crystal comprises three or more material layers and two or more polarization orientations, each polarization orientation being associated with a different pair of stacked material layers.

In another aspect there is thus provided a multipolarized diatomic hexagonal multilayered material, the material comprising two or more material layers oriented in a parallel lattice orientation to each other and two or more polarization domains.

In some embodiments, the polarized or multipolarized system is stable at room temperature, as defined herein.

Polarization orientation may be switched by applying electric field to the polarized multilayered material. By inducing electric field, ferroelectricity may be induced that is stable at room temperature, namely at a temperature up to 200° C. In some embodiments, stability is measured at an ambient temperature, namely at a temperature between 20 and 200° C. As used herein, the term “room temperature stable” or any variation thereof refers to the fact that a polarized material or a ferroelectric material according to the invention does not exhibit diminishing or loss of electric field (polarization) or ferroelectricity at temperatures as high as room temperature, or up to 200° C.

Thus, it is an object of the present application to further provide a process for inducing ferroelectricity to a polarized diatomic hexagonal layered material, such as h-BN and TMD, the process comprising applying a local electric field normal to a polarized diatomic hexagonal (multi) layered material causing domain wall sliding, thereby flipping the polarization orientation and inducing the ferroelectricity.

Also provided is a process for manufacturing a room temperature stable ferroelectric crystal, the process comprising forming or obtaining a diatomic hexagonal multilayered material having a layered stacking configuration, wherein the material layers are stacked in a parallel lattice orientation to exhibit internal interfacial electric field normal to the layer plane of the crystal and applying electric field to said layered material to induce room temperature stable ferroelectric properties.

The term “ferroelectricity” is attributed to a polarized material or system that can switch its internal polarization orientation by applying external electric field.

This electric polarization can be reversed in direction by the application of an opposite electric field to the polarized domains. The polarization and its switching process are stable at room temperature and ambient conditions.

In some embodiments, electric field is applied by scanning a biased tip above the hexagonal diatomic layered material surface to induce a local electric field normal to interface.

In some embodiments, the process of the invention thus aims at achieving a dynamic flipping of polarization orientation by domain-wall sliding. This is achieved, in some embodiments, by a process comprising:
scanning a biased tip above the structure surface, to induce a local electric field normal to the interface;
selecting negative or positive bias to the tip;
to thereby endow a domain of said material with a positive or negative normal polarization orientation.

In place of a scanning biased tip, an electrode may be used.

The “domain wall” defines a boundary between or an interface separating crystallographic domains in the material or crystal. In “domain wall sliding” a relative lateral shift by one interatomic distance occurs in one of the layers of the layered materials, relative to an underlining layer, which causes switching of the layers stacking configuration. The switched stacking is equivalent to flipping of the structure and its normal polarization orientation. In other words, the lateral domain walls sliding increases the area of the domains that point along the external electric field at the expense of the domains that point in the opposite direction as shown in FIG. 3.

Thus, the invention further provides a process for manufacturing a room temperature stable ferroelectric crystal, the process comprising applying a local electric field normal to a polarized crystal of a diatomic hexagonal layered material, such as h-BN and TMD crystals to thereby cause sliding of layers in said layered material relative to each other, to provide an array of permanent and switchable polarization domains in the crystal.

Further provided is a process for manufacturing a room temperature stable ferroelectric crystal, the process comprising forming a crystal of a diatomic hexagonal layered material having a layered stacking configuration, such as h-BN crystal, wherein the material layers are stacked in a parallel lattice orientation to exhibit internal interfacial electric field normal to the layer plane of the crystal (namely to having polarization) and applying electric field to said layered material to induce ferroelectric properties.

In another aspect of the invention, there is provided a ferroelectric diatomic hexagonal layered material, such as h-BN and TMD crystals.

Also provided is a polarized diatomic hexagonal layered material or crystal, namely a material or a crystal exhibiting internal interfacial electric field normal to a layer plane of the material or crystal.

Further provided is a diatomic hexagonal layered material or crystal exhibiting multiple polarization states or orientations normal to a layer plane of the material or crystal. In other words, each polarization state or orientation being located at a different internal interface between layers of the material or crystal.

In some embodiments, the polarized or ferroelectric material is manufactured according to any of the processes of the invention.

Ferroelectric materials of the invention or materials manufactured according to processes of the invention may be implemented in a variety of devices and can be used in a variety of applications. In most general terms, a device is provided that comprises a ferroelectric material according to the invention. The device may be an electronic or a photoelectric or an optical device.

Ferroelectric materials of the invention offer significant advantages in integrated circuits, particularly integrated circuit memories. As known in the art, integrated circuit memories, including conventional Dynamic Random Access Memory (DRAM), are volatile memories, in which the stored information remains only so long as power is applied to the integrated circuit. Non-volatile memories, such as flash-type memories, are low in storage density, require extremely high voltage applied for long periods to write and erase data, and generally have a more limited erase and write lifetime than DRAMs. The ferroelectric materials having polarization states that can be selected or switched by application of an electric field, and these polarization states remain after the electric field is removed can be used as capacitors possibility for simple, low cost, high density, non-volatile memories.

Apart from the memory units, ferroelectric materials of the invention may be utilized in ferroelectric field effect transistors, high capacity dynamic random access memories (DRAMs), CCD multiplexer read-out systems, integrated pyroelectric detectors, integrated surface acoustic wave devices, spatial light monitors, and microwave devices as well as in ferroelectric tunnel junction, ferroelectric transistors, sensors and strain sensors, and a variety of optical devices.

Also provided is use of a ferroelectric material according to the invention in constructing an electronic or a photoelectric or an optical device, as detailed herein.

As noted above, polarization and polarization magnitude of a multilayered structure according to the invention may be determined. Having the ability to pre-set or pre-define the polarization states in a multilayered structure enables designing a multi-switch device having pre-determined multi-switch polarization states. Thus, devices of the invention may be configured also as having pre-determined multi-switch polarization states, each of said states being determined by summing up the (total) number of interfaces having a polarization pointing in one direction (e.g., “up”) normal to the multilayer plane, minus the number of interfaces with a polarization pointing in the opposite direction (e.g., down).

As noted herein, polarization states can be reversed in direction by the application of an opposite electric field to the polarized domains. The polarization and its switching process are stable at room temperature and ambient conditions.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIGS. 1A-1D show various high symmetry interlayer stacking configurations. (A) Top view illustration of two layers. For clarity, atoms of the top layer are represented by small circles. For either group of parallel/anti-parallel twist orientations, a relative lateral shift by one lattice spacing results in a cyclic switching between three high-symmetry stacking configurations. (B) Local-registry index (LRI, defined in SM) map of two nearly parallel rigid layers with a twist angle of 0.5°. Blue regions correspond to AA stacking, whereas AB/BA stacking appear in orange (LRI=0.86). (C) Calculated LRI map after geometry relaxation of the structure presented in panel (B). Large domains of uniform untwisted AB/BA stacking appear, on the expense of the pre-optimized AA regions. The twist is accumulated in smaller AA—like regions and in the ˜10 nm wide incommensurate domain walls (bright lines), see FIG. S1 and SM for further discussion. (D) Cross-sectional illustration of two few-layered flakes (blue and light blue regions marked the top and bottom flakes, respectively) of naturally grown h-BN (AA′), which are stacked with no twist. Plus (minus) signs mark boron (nitrogen) sites. A topographical step of a single layer switches between parallel and anti-parallel stacking orientations at the interface between the two flakes. Vertical charge displacements and the resulting net polarization P_z are marked by arrows.

FIGS. 2A-2D show direct measurement of interfacial polarization. (A) Illustration of the experimental setup. An atomic force microscope is operated in Kelvin-probe mode to measure the local potential modulation, VKP, at the surface of two 3 nm thick h-BN flakes, which are stacked with a minute twist angle. (B) VKP map showing oppositely-polarized domains of AB/BA stacking (black and white), ranging in area between ˜0.01 and 1 μm2 and separated by sharp domain-walls. (C) Surface potential along the purple line marked in (B). (D) DFT calculations of the polarization P_z per unit area in two-layer (black triangles) and four-layer (blue square) finite h-BN stacks of different lateral dimensions. The out-of-plane polarization estimated based on the measured potential is shown on the right (red star).

FIG. 3 shows the dynamic flipping of polarization orientation by domain-wall sliding. Kelvin-probe maps measured consequently from left to right above a particular flake location showing domains of up (white) and down (black) polarizations. The middle image was taken after biasing the tip by a fixed DC voltage of −20 Volts and scanning it above the blue square region shown on the left-hand image. Then the tip was biased by 10 Volt and scanned again over the same region before taking the right-hand image. Consequent domain-walls positions are marked by dashed red, green, and yellow lines. Larger white (black) domains appear after positive (negative) bias scans as a result of domain-wall motions. Note that the number of domain-walls is apparently not altered.

FIGS. 4A-D show a geometric relaxation of a Moire pattern. (A) Atomic configuration of a relaxed periodic twisted bilayer h-BN with a twisted angle of θ=0.5° . The size of the entire model system is 48.9 nm×84.7 nm B and N atoms are colored by ochre and blue, respectively. Distinctly colored AB and BA domains are obtained since atoms of the upper layer hide those of the bottom layer that reside exactly below them. (B) Interlayer distance map for the relaxed twisted bilayer. (C) The energy variation during the minimization cycles applied to the model system appearing in panel (A) plotted relative to the initial energy. The first ten points represent cycles with force tolerance set to [symbol] 10 [symbol] \hat{ }(−3) eV/Å and the last point corresponds to the final minimization step with force tolerance of [symbol] 10 [symbol] \hat{ }(−4) eV/Å. (D) Interlayer distance (red) and local registry index (black) along the path marked by the black dashed line in panel B. The reference LRI values of the AA and AB/BA stacking modes are −1 and 0.86 (marked by the corresponding horizontal lines).

FIGS. 5A-D show topography maps of the interface of the crystals. (A, B) Surface potential and topography maps measured simultaneously on the structure presented in the main text (FIG. 2B). The top h-BN flake thickness is uniform and includes 10 layers. Topography steps in the surface of the bottom flake are marked by dashed red lines, and its total thickness at different positions is indicated. (C, D) Additional interface between a thick (>1000 layers) bottom flake and a thin (4-7 layers) top flake. Similar potential drops between the domains are observed independent of the thickness of the structures or the substrate: graphite (SiO2) in A (C) respectively.

FIGS. 6A-D show a series of Mulliken charge distribution maps. (A) Top view of the relaxed AB stacked hydrogen terminated finite bilayer h-BN flake of 1.1 nm2 contact area. Pink, blue and white spheres represent boron, nitrogen, and hydrogen atoms, respectively. (B) The Mulliken atomic charge map of (A) calculated at the B3LYP/Def2TZVP level of theory. (C) and (D) same as (A) and (B) but for the 2.9 nm2 contact area system, respectively.

FIGS. 7A-E show series of stacked bilayer and interspacing models. (A) Top view of AB (left) and AA′ (right) stacked bilayer h-BN. The top (bottom) layer atoms are marked by small (large) circles. Lattice sites that participate in the forces F_(11 (12)) in Eq. (S9) are marked by dashed green (solid red) arrows, respectively. Similar to AA′, the eclipsed atoms in AB experience both forces, however, the hollow atoms include only F_12 (twice). Also note the zero Coulomb force in the latter case due to opposite charges of yellow/blue sites. (B) Cross section of AB stacked bilayer h-BN along the dotted black line marked in (A). α(β) indicates hollow (eclipsed) sites respectively. (C) Convergence of the total interlayer Coulomb force for h=3.3 Å with the number of Bravais lattice vectors (n_m) in the summation in Eq. (S9). (D) Inter-layer spacing (h) calculated for AA′ (solid lines) and AB (dashed lines) stacked bilayer h-BN, for different fixed values of cohesion/Coulomb ratio ε/q\hat{ }2. Black lines with q=0 correspond to graphite and show smaller h for AB than AA′ stacking as expected, while orange lines with ε/q\hat{ }2=1.5 meV show the opposite, as expected for h-BN. (E) Intra-layer displacement (marked in B) as a function of ε/q\hat{ }2. The estimated value from the experiment is marked by a red star, suggesting ε/q\hat{ }2˜3 meV.

FIG. 8 shows examples of domain-wall sliding. Consequent KPFM images of the same flake location (from left to right-hand side). Between the images a biased tip (±10 V) was scanned above the region marked by a blue square. Positive tip bias resulted in domain-wall motion that increased the white domains area over the black domains and vice versa.

FIG. 9 shows the out of plane polarization of an AB stacked multi-layer system. The out-of-plane polarization as a function of number of layers for the fully AB stacked multilayer system (squares) compared to the results presented in FIG. 10A (circles). The polarization was calculated using Gaussian.

FIGS. 10A-10C provide polarization in TMDs. (A) Potential map at the surface of three WSe2 layers stacked in a parallel orientation. Five fixed potential values are measured corresponding to the five different orientation configurations of two independent polarizations. Scale bar is 1 μm. (B) The potential difference between oppositely polarized domains is 120 mV and 240 mV for one and two interfaces respectively (dashed line cuts as shown in A). (C) DFT calculation of the potential along the cross section the two interfaces. The measured and calculated values for single and double interfaces confirm the linear polarization increase with the number of layers.

### DETAILED DESCRIPTION OF THE INVENTION

As disclosed herein, the invention provides a process for inducing polarization in a stacked multilayered diatomic hexagonal material, the process comprising orienting any two stacked layers of a diatomic hexagonal multilayered material into a stacked parallel lattice orientation to induce internal interfacial electric field normal to the layers plane at an interface between the two stacked material layers.

In some embodiments, the process comprises layering two or more flakes of a diatomic hexagonal material such that a stacked multilayered material is obtained wherein each layer in the multilayered material is in a parallel lattice orientation.

In some embodiments, the process comprises depositing a layer of a diatomic hexagonal material on top a layer of same diatomic hexagonal material such that a stacked multilayered material is obtained wherein each layer in the multilayered material is in a parallel lattice orientation.

In some embodiments, the process comprises providing a diatomic hexagonal multilayered crystal or material, separating layers making up the crystal or material into separate layers and stacking at least one of the separated layers on top of another, such that an internal interfacial electric field normal to the layers plane of the material is formed at an interface between the two stacked material layers.

In some embodiments, the process comprises
providing two or more flakes of a diatomic hexagonal material;
stacking the two or more flakes into a multilayered material, wherein each layer in the multilayered material is in a parallel lattice orientation.

In some embodiments, the two or more flakes are obtained from exfoliating layers of a diatomic hexagonal multilayered crystal or material.

In some embodiments, the number of layers in the multilayered material is at least two.

In some embodiments, the number of layers in the multilayered material is two or three or more.

In some embodiments, the number of polarization states is equal to the number of internal interfaces between stacked layers in the multilayered material.

In some embodiments, the number of polarization states is one or is at least two.

In some embodiments, the process is for obtaining a polarized diatomic hexagonal multilayered material having one or two or more same or different internal interfacial polarized states.

In some embodiments, the diatomic hexagonal multilayered material is selected from hexagonal-boron-nitride (h-BN), transition-metal-dichalcogenides (TMD), hexagonal-aluminum-nitride (h-AlN), hexagonal-zinc-oxide (h- ZnO) and hexagonal-gallium-nitride (h-GaN).

In some embodiments, the material is hexagonal-boron-nitride (h-BN) or transition-metal-dichalcogenides (TMD).

In some embodiments, the TMD is selected from MoS₂, WS₂, MoSe₂ and WSe₂.

In some embodiments, the process is for inducing polarization in a h-BN crystal.

In some embodiments, the process is for inducing polarization in a TMD crystal.

Also provided is a diatomic hexagonal multilayered material, the material comprising two or more material layers oriented in a parallel lattice orientation to each other, exhibiting or having internal interfacial electric field normal to the layers plane.

In some embodiments, the material has one or more internal interfacial electric fields (or polarization domains), each being at a different interface between two stacked layers.

Further provided is a multipolarized diatomic hexagonal multilayered material, the material comprising two or more material layers oriented in a parallel lattice orientation to each other and two or more polarization domains.

In some embodiments, the diatomic hexagonal multilayered material is selected from hexagonal-boron-nitride (h-BN), transition-metal-dichalcogenides (TMD), hexagonal-aluminum-nitride (h- AlN), hexagonal-zinc-oxide (h- ZnO) and hexagonal-gallium-nitride (h- GaN).

In some embodiments, the material is hexagonal-boron-nitride (h-BN) or transition-metal-dichalcogenides (TMD).

In some embodiments, the TMD is selected from MoS₂, WS₂, MoSe₂ and WSe₂.

In some embodiments, the material is stable at room temperature.

In some embodiments, the material is prepared by a process according to processes of the invention.

In some embodiments, the material has three or more material layers, a magnitude of polarization of the material is equal to a polarization measured or determined for a single interface between two stacked layers multiplied by the number of layer interfaces.

In some embodiments, the material is characterized by a linear enhancement of polarization, wherein the magnitude of polarization being dependent on the number of interfaces between any two stacked layers.

In some embodiments, the material is characterized by diminished depolarization surface effects.

The invention further provides a process for inducing ferroelectricity to a polarized diatomic hexagonal multilayered material, the process comprising applying a local electric field normal to a polarized diatomic hexagonal multilayered material causing domain wall sliding, to thereby induce the ferroelectricity.

In some embodiments, the process comprises applying a local electric field by an electrode or a biased tip above the hexagonal diatomic multilayered material surface.

In some embodiments, the process is for manufacturing a room temperature stable ferroelectric crystal, the process comprising applying a local electric field normal to a polarized crystal of a diatomic hexagonal multilayered material, to thereby cause sliding of layers in said layered material relative to each other, to provide an array of permanent and switchable polarization domains in the crystal.

A process is also provided for manufacturing a room temperature stable ferroelectric crystal, the process comprising forming or obtaining a diatomic hexagonal multilayered material having a layered stacking configuration, wherein the material layers are stacked in a parallel lattice orientation to exhibit internal interfacial electric field normal to the layer plane of the crystal and applying electric field to said layered material to induce room temperature stable ferroelectric properties.

In some embodiments, the number of layers in the multilayered material is at least two.

In some embodiments, the number of layers in the multilayered material is two or three or more.

In some embodiments, the polarized diatomic hexagonal multilayered material has one or more same or different internal interfacial polarized states.

In some embodiments, the process is for inducing ferroelectric properties to h-BN crystal.

In some embodiments, the process is for inducing ferroelectric properties to TMD crystal.

Also provided is a diatomic hexagonal multilayered material having room temperature stable ferroelectric properties.

In some embodiments, the material is h-BN or TMD.

In some embodiments, the material is prepared by a process according to the invention.

A use is provided of a ferroelectric material according to the invention in constructing an electronic or a photoelectric or an optical device.

A device may be any such device implementing a ferroelectric material according to the invention. The device may be selected from integrated circuits, such as an integrated circuit memory.

In some embodiments, the device is selected from Dynamic Random Access Memory (DRAM), a flash-type memory, a ferroelectric field effect transistor, a CCD multiplexer read-out system, an integrated pyroelectric detector, an integrated surface acoustic wave device, a spatial light monitor, a microwave device, a ferroelectric tunnel junction, a ferroelectric transistor, a sensor and strain sensor.

A device implementing a material according to the invention may have pre-determined multi-switch polarization states, each of said states being determined by summing up the number of interfaces having a polarization pointing in one direction normal to the multilayer plane, minus the number of interfaces with a polarization pointing in the opposite direction.

In the following description, numerous details are set forth for the purpose of explanation. However, one of ordinary skill in the art will realize that the invention may be practiced without the use of these specific details.

### Materials and Methods

### a) Device Fabrication

h-BN flakes of various thicknesses (1-5 nm) were exfoliated onto a SiO₂ surface. A particular flake is selected to have several topographic steps of a few-layers thickness. The flake is ripped off into two pieces which are stacked together by a polymer stamp. During the stamping processes we make sure to minimize any twist orientation. Finally, the two-flakes-sandwich is placed on a conducting graphite flake or alternatively on a gold substrate, using the same dry transfer method.

### b) AFM Scans

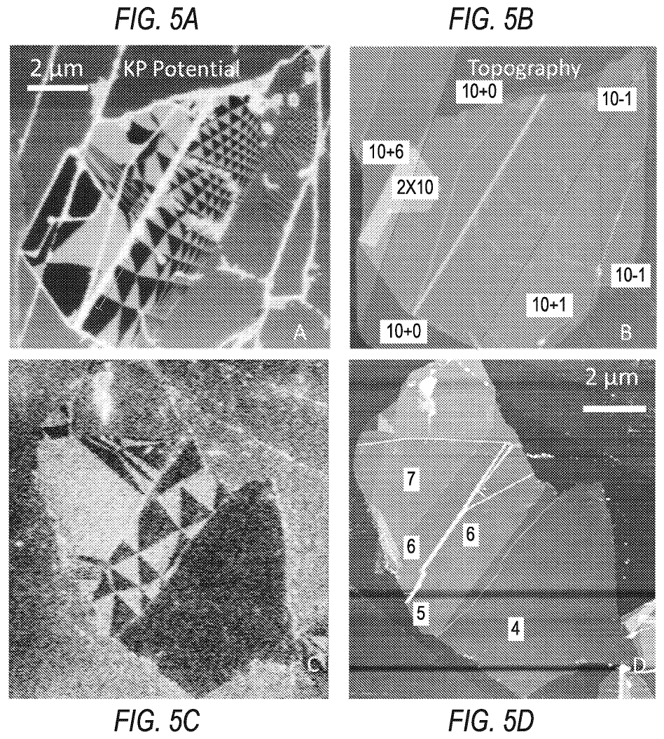

Topography and Kelvin probe force microscopy (KPFM) measurements are acquired simultaneously (FIG. 5), using Park System NX10 AFM in a non-contact scanning mode. The electrostatic signal is measured in the first harmonic using a built-in lock in amplifier. We use Multi-75g and PPP-EFM n-doped tips with conductive coating. The mechanical resonance frequency of the tips is 75 kHz, and the force constant is 3 N/m. The cantilever is oscillated mechanically with an amplitude of ˜20 nm. The cantilever is also excited with an AC voltage to perform KPFM measurements as described below, with amplitude of 3-6 V and frequency of 17 kHz. The DC voltage is controlled by a servo motor to obtain the surface potential measurements. The images are acquired using Park SmartScan software and the data analysis is performed with Gwyddion program.

To switch the domain orientation biased scans are performed in a pin-point mode. Here the tip approaches the surface vertically at each pixel in the scanned area. The estimated maximum force during this approach is 50 nN. This mode minimizes lateral forces between the tip and the surface.

### c) Kelvin-Probe Surface Potential Measurements

The AFM tip and the sample are treated as a parallel-plate capacitor model. The charge induced on the tip and the substrate is affected by the voltage applied between them, and potential drops related to the sample.

The applied voltage on the tip consists of DC and AC components. The total voltage is given by:

V=V_{DC}+V_{AC} sin(ωt)+V_{CPD}

where V_{CPD} is the contact potential difference, which originates from the different work function of the tip and the substrate. The force acting on the tip is:

$$F = \frac{A}{2 ϵ} {ρ}^{2} ,$$

where A is the effective area of the capacitor, ϵ is the dielectric constant and ρ is the two-dimensional charge density. The latter can be extracted from:

$$V = \frac{ρ}{ϵ} d + {V}_{int} ,$$

where d is the distance between the plates, and Vᵢₙₜ is the voltage drop at the h-BN interface. This claim holds assuming the sample is neutral and the field outside the sample from the charges distribution in the sample is zero. After inserting it in the force equation, we get the first harmonic of the force:

F(ω)∝(Vᵢₙₜ−V_{DC}−V_{CPD})_{AC} sin(ωt)

It vanishes for V_{DC}=Vᵢₙₜ−V_{CPD}. The main principle of KPFM is to apply a DC voltage that nullifies the first harmonic, so Vᵢₙₜ signal can be extracted from variation in the KPFM signal, V_{DC}, at different lateral positions above the surface.

### d) Model System and Classical Force-Field Calculations

To study the structural properties of twisted h-BN interfaces we constructed a model system consisting of two h-BN layers with an interlayer misfit angle of ˜0.5°. To mimic the experimental scenario, a laterally periodic supercell was constructed with a triangular lattice of periodicity L=|n\vec{a}₁+m\vec{a}₂|, where the primitive lattice vectors are given by \vec{a}₁=a_{hBN}(\sqrt{3,} 0) and

$${\vec{a}}_{2} = \frac{{a}_{h B N}}{2} ( \sqrt{3} , 3 )$$

a_{hBN}2.505 Å based on the Tersoff potential equilibrium bond-length of b_{BN}=1.446 Å. The indices n=195 and m=1 were chosen to fulfil the condition:

$$cos ( θ ) = \frac{2 {n}^{2} - {m}^{2} + 2 nm}{2 ( {n}^{2} + {m}^{2} + nm )} . \qquad ( S1 )$$

The corresponding moiré pattern dimension is

$$L = \frac{{b}_{B N}}{\sqrt{2 - 2 cos ( θ )}} = 16.3 nm .$$

The parallelepiped supercell was then multiplicated to construct a rectangular supercell consisting of more than 300,000 atoms.

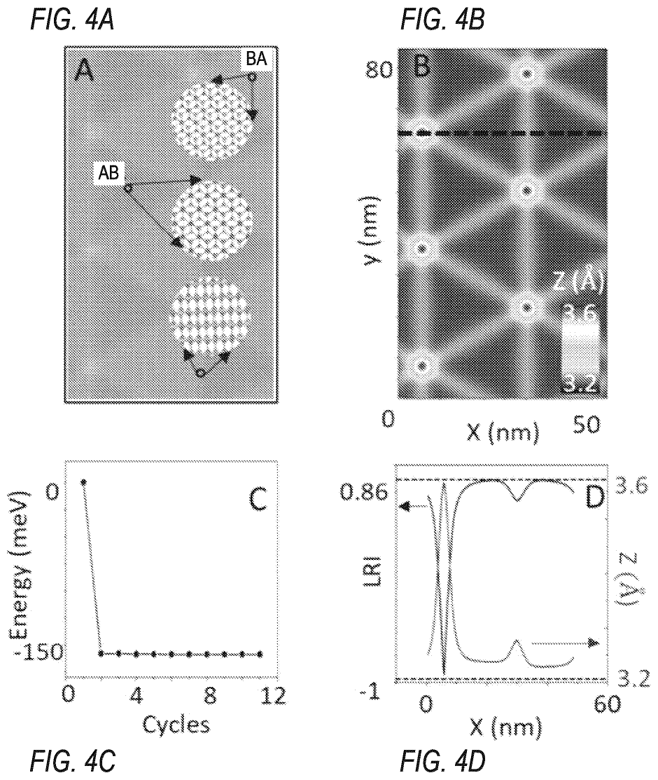

The structural properties of the twisted h-BN interface were calculated using the Tersoff intra-layer potential in conjunction with the recently developed dedicated interlayer potential (ILP). We first optimized the geometry of the top layer atoms with fixed supercell size using the Fire algorithm and keeping the bottom layer rigid. This was followed by optimization of the supercell dimensions by the conjugate gradient (CG) algorithm while scaling the rigid bottom layer according to the simulation box size. This two-step energy minimization procedure was repeated for ten times, which is sufficient to obtain well converged results (see FIG. 4C). In each repetition, both minimization stages were terminated when the forces acting on each degree of freedom reduced below 10⁻³ eV/Å. The system was further relaxed by Fire algorithm at a force tolerance of 10⁻⁴ eV/Å. The optimized structure exhibits atomic reconstruction with distinct AB and BA stacking domains separated by domain walls (see FIG. 4A).

### e) Local Registry Index Analysis

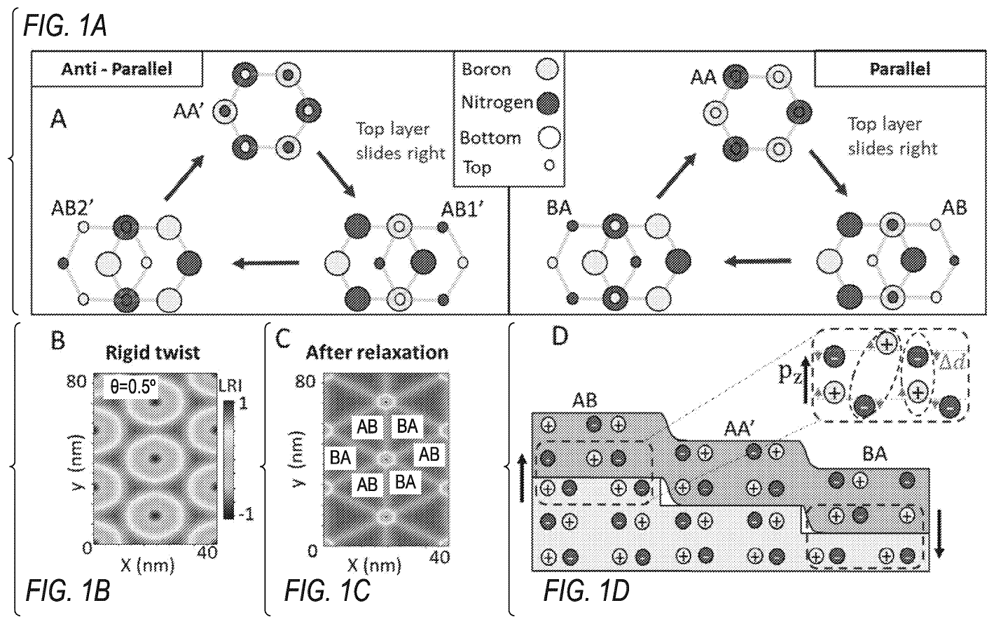

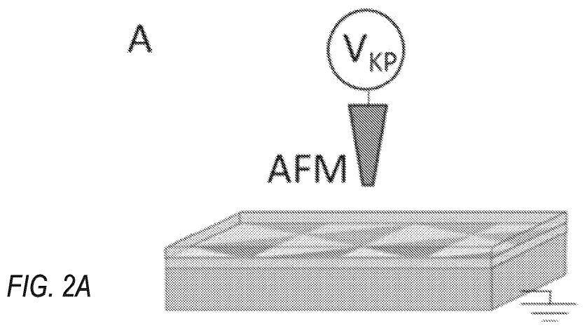

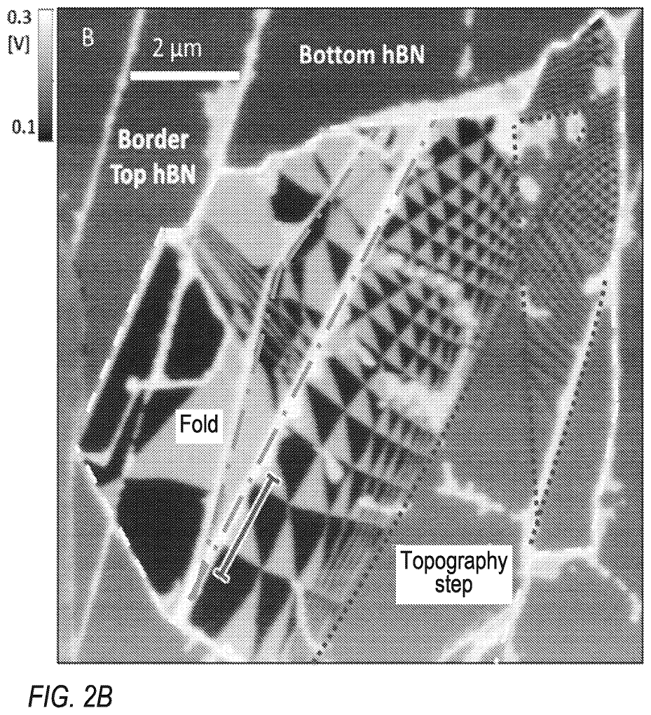

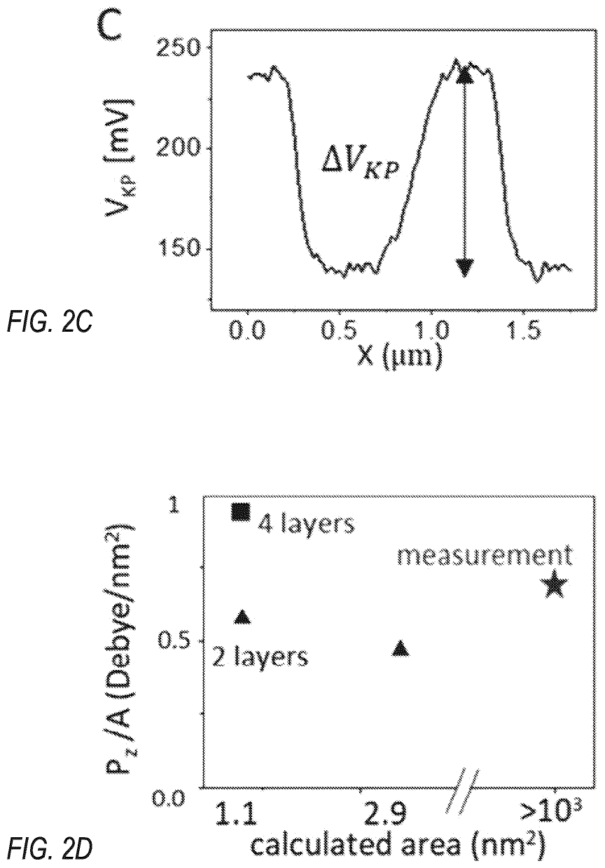

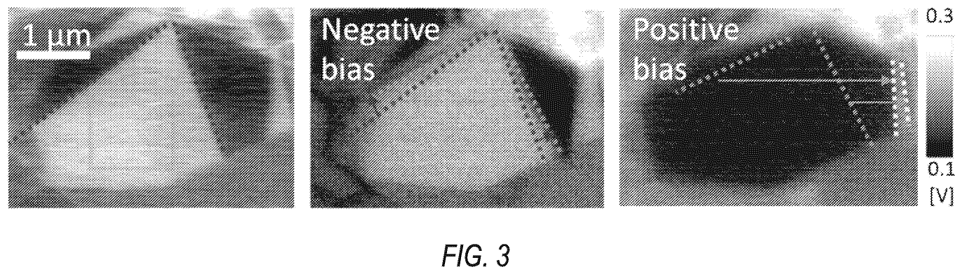

The local registry index (LRI) (FIG. 1D) is a method introduced to quantify the degree of local interfacial registry matching at rigid material interfaces. The idea is to assign a number between −1 and 1 to each atom in the layer, signifying whether it resides in an optimal or worse stacking region, respectively. To this end, a circle is associated with each atomic position in the two layers and the overlaps between circles of one layer and those of the adjacent layer are evaluated. For the case of h-BN three types of overlaps are considered, namely Sᵢ^{NN}, Sᵢ^{NB}ᵢ=Sᵢ^{BN}, and S^{BB}ᵢ. Here, Sᵢ^{JK}signifies the overlap of the circle associated with atom i of type J in one layer with all circles associated with K type atoms in the adjacent layer. The radius of the circles associated with B and N atoms is taken as r_{B}=0.15b_{hBN}, and r_{N}=0.5b_{nBN}, which provides good qualitative agreement between registry index maps and the sliding potential energy surfaces obtained from density functional theory calculations. The LRI of atom i is then defined as the average registry index of itself and its three nearest neighbors (j, k, l) within the entire layer, as follows:

$${LRI}_{i} = \frac{1}{3} {\sum }_{n = j , k , l} \frac{[ ( {S}_{i}^{N N} + {S}_{n}^{N N} ) - ( {S}_{i}^{NN , opt} + {S}_{n}^{NN , opt} ) ] + [ ( {S}_{i}^{B B} + {S}_{n}^{B B} ) - ( {S}_{i}^{BB , opt} + {S}_{n}^{BB , opt} ) ] - [ ( {S}_{i}^{N B} + {S}_{n}^{N B} ) - ( {S}_{i}^{NB , opt} + {S}_{n}^{NB , opt} ) ]}{[ ( {S}_{i}^{NN , worst} + {S}_{n}^{NN , worst} ) - ( {S}_{i}^{NN , opt} + {S}_{n}^{NN , opt} ) ] + [ ( {S}_{i}^{NN , worst} + {S}_{n}^{NN , worst} ) - ( {S}_{i}^{NN , opt} + {S}_{n}^{NN , opt} ) ] + [ ( {S}_{i}^{NB , worst} + {S}_{n}^{NB , worst} ) - ( {S}_{i}^{NB , opt} + {S}_{n}^{NB , opt} ) ]} \qquad ( S2 )$$

where Sᵢ^{JK,opt} and Sᵢ^{JK,worst} are Sᵢ^{JK} evaluated at the optimal and worst local stacking modes, respectively (AA′ and AA in the case of h-BN, respectively, see FIG. 1A). The calculated LRIᵢ is then transformed by −(2LRᵢ−1) to make it range be between [−1, 1]. With this, the LRI at an AA′ (AA) stacked region is 1 (−1) respectively, and that of an AB stacked region is 0.86.

Plotting the LRI following geometry relaxation as discussed above (FIG. 1D) we found an ordered array of AB and BA stacked domains separated by sharp domain walls. To estimate the width of the domain-wall region, we plotted a cross section of the out-of-plane height profile (see FIG. 4D) along the path marked by the dashed black line in FIG. 5B. A clear inverse correlation between the height map (red line) and the registry index (black line) is obtained. At the AB and BA stacked regions the interlayer distance is relatively constant at ˜3.23 Å and correspondingly a relative constant value of LR˜0.86 is obtained. At the center of the domain wall, the interlayer distance increases by ˜0.05 Å and the LRI reduces to ˜0.67, whereas at the domain wall crossings the interlayer distance reaches ˜3.57 Å and the LRI drops to ˜−0.93. Using a Gaussian fitting to the height profile near the domain wall we can estimate the domain wall width to be ˜10 nm.

### f) Dipole Moment Calculations

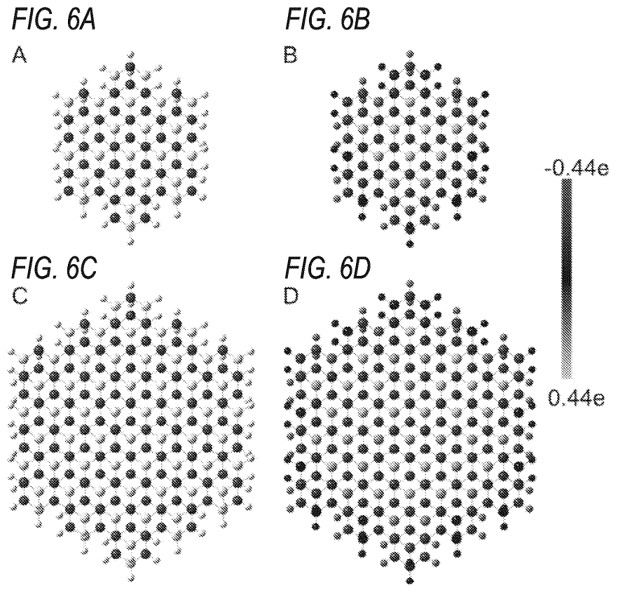

To evaluate the dipole moment developing in the system we considered a finite AB stacked hexagonal h-BN bilayer model with a surface area of 1.1 nm² and armchair edges. The flake was initially constructed with uniform B—N bond lengths of 1.446 Å and the edges were saturated by hydrogen atoms with initial B—H and N—H bond lengths of 1.200 Å and 1.020 Å, respectively (FIG. 6A,C). The structures were optimized using the hybrid B3LYP exchange-correlation density functional approximation and the double-ζ polarized 6-31G** Gaussian basis set as implemented in the Gaussian 16 suite of programs. This was followed by refined relaxation adding Grimme's D3 dispersion correction and using the 6-31+G** basis set. Finally, single point calculations were performed on the minimized structures at the B3LYP/6-31+G** and B3LYP/Def2TZVP level of theory. Comparison of the out-of-plane dipole moment components obtained using the three basis sets is provided in Table 1, showing that our results are well converged with respect to basis set size. The value calculated by Def2TZVP was used in FIG. 1C in the main text.

To verify that the flake size used is sufficiently large, we repeated the dipole moment calculation for a bilayer flake with surface area of 2.9 nm². As seen in Table 1 the obtained values are within 20-25% with those of the smaller flake, indicating that edge effects are relatively small and validating the qualitative value of the results. This is further supported by the Mulliken charge analysis map provided in FIG. 6B, D, showing that most of the charge is located in the bulk region of the flakes.

TABLE 1
The out-of-plane dipole moments (p_{z}) obtained for
two AB stacked bilayer h-BN finite flake models.

| | Dipole moment (Debye/nm²) | | |
|---|---|---|---|
| Area (nm²) | 6-31G** | 6-31 + G** | Def2TZVP |
| 1.1 | 0.66 | 0.55 | 0.55 |
| 2.9 | 0.52 | 0.45 | 0.45 |

### g) Minimalistic Classical Cohesive Energy Model

Our minimalistic model provides a classical estimate of the out-of-plane polarization of the AB bilayer interface treating the boron and nitrogen atoms as point charges (see FIG. S4A,B), interacting via Pauli and van der Waals (VdW) forces (described by the Lennard-Jones (LJ) potential), and Coulomb interactions. The total interlayer energy is written as follows:

$$E = \frac{1}{2} {\sum }_{i , j} [ 4 ε ( {( \frac{σ}{{r}_{i j}} )}^{12} - {( \frac{σ}{{r}_{i j}} )}^{6} ) + \frac{{q}_{i} {q}_{j}}{{r}_{i j}} ] , \qquad ( S3 )$$

where ε is the cohesive energy with σ≡3.3 Å. We note that realistic models of h-BN should take atom specific ε and σ values. Here, however we are interested in a qualitative description of the system and hence, for simplicity, we limit the treatment for uniform parameter values. The differences in electronegativity of the boron and nitrogen atoms are effectively taken into account by assigning dimensionless partial charges located at the nuclear centers q=±qᵢ/e for i∈B, N respectively. The parameter q²/εσ controls the relative strength between the Coulomb and LJ interactions. As we will demonstrate, this competition determines the sign of the polarization at the AB interface. We denote by α the atomic sites in one layer that reside above hexagon centers in the other layer (termed herein as hollow sites). Correspondingly, β denotes atomic sites in one layer that reside above oppositely charged sites on the adjacent layer (termed herein as eclipsed sites). In each layer we use h_{α} or h_{β} to denote vertical heights of α and β atomic sites, measured with respect to the midplane of the AB interface. To compute the polarization, we minimize the classical energy with respect to h_{α}, h₆₂ , via an approximate two-step protocol:
1. First, we set h_{α}=h₆₂ =h/2 and minimize the interaction energy with respect to h.
2. Then we allow for finite relative vertical motion of B-N pairs around the optimal h value 2Δd=h_{α}−h_{β}, which generates the polarization. Note that no lateral atomic motion is allowed.

### Optimal Interlayer Spacing at the AA′ Stacking Mode

As a reference, we first consider two h-BN layers in the AA′ stacking configurations with h_{α}=h_{β}=h/2. The total force per atom is:

$${F}_{AA '} ( h ) = - \frac{{dE}_{{AA}^{′}} ( h )}{dh} = {F}_{AA '}^{LJ} + {F}_{AA '}^{C} \qquad ( S4 )$$

The Coulomb contribution can be written as F_{AA′}^{C}=−F₁₁^{C}+F₁₂^{C} (with F₁₁^{C}, F₁₂^{C}>0), where

$$\begin{matrix}{F}_{11}^{C} ( h ) = {\sum }_{{\vec{R}}_{11}} \frac{{e}^{2} h}{{( {\vec{R}}_{11}^{2} + {h}^{2} )}^{3 / 2}} , & {F}_{12}^{C} ( h ) = {\sum }_{{\vec{R}}_{12}} \frac{{e}^{2} h}{{( {\vec{R}}_{12}^{2} + {h}^{2} )}^{3 / 2}}\end{matrix} . \qquad ( S5 )$$

Here, \vec{R}₁₁=\vec{R}_{n1,n2} denote in plane lattice vectors connecting equivalent atoms, namely Bravais lattice vectors, and \vec{R}₁₂=\vec{R}_{n1,n2}−\hat{x}R₀ denote in plane lattice vectors connecting inequivalent atoms, where \hat{x}R₀ is a vector connecting nearest-neighbors. The corresponding Bravais lattice vectors of the honeycomb lattice are given by \vec{R}ₙ_{₁}_{,n}_{₂}=n₁\vec{R}₁+n₂\vec{R}₂, and

$${\vec{R}}_{1 , 2} = {R}_{0} ( \frac{3}{2} , \pm \frac{\sqrt{3}}{2} ) ,$$

with R₀=1.4 Å. Quick convergence of F_{AA′}^{C}, is guaranteed if for any pair of integers n₁, n₂ the term F₁₁^{C}(h) is combined with F₁₂^{C}(h) calculated for −n₁, −n₂ and the sums are taken over the range −nₘ≤n₁, n₂≤nₘ with sufficiently large nₘ. The force then converges as 1/nₘ² (not shown) in FIG. S4C. Notably, the attractive force e²/h² associated with a single vertical bond is strongly suppressed due to the alternating charges within the layer and the small ratio R₀/h. This reduces the bare Coulomb interlayer energy

$$\frac{{e}^{2}}{h} ∼ 4.3 eV$$

into the meV regime, comparable with the VdW scale ε⁴³.

Similarly, the LJ force can be split as F_{AA′}^{LJ}=F₁₁^{LJ}+F₁₂^{LJ}, where

$${F}_{11}^{L J} ( h ) = 4 ε {\sum }_{{\vec{R}}_{11}} ( \frac{12 {σ}^{12} h}{{( {\vec{R}}_{11}^{2} + {h}^{2} )}^{7}} - \frac{6 {σ}^{6} h}{{( {\vec{R}}_{11}^{2} + {h}^{2} )}^{4}} ) , {F}_{12}^{L J} ( h ) = 4 ε {\sum }_{{\vec{R}}_{12}} ( \frac{12 {σ}^{12} h}{{( {\vec{R}}_{12}^{2} + {h}^{2} )}^{7}} - \frac{6 {σ}^{6} h}{{( {\vec{R}}_{12}^{2} + {h}^{2} )}^{4}} ) . \qquad ( S6 )$$

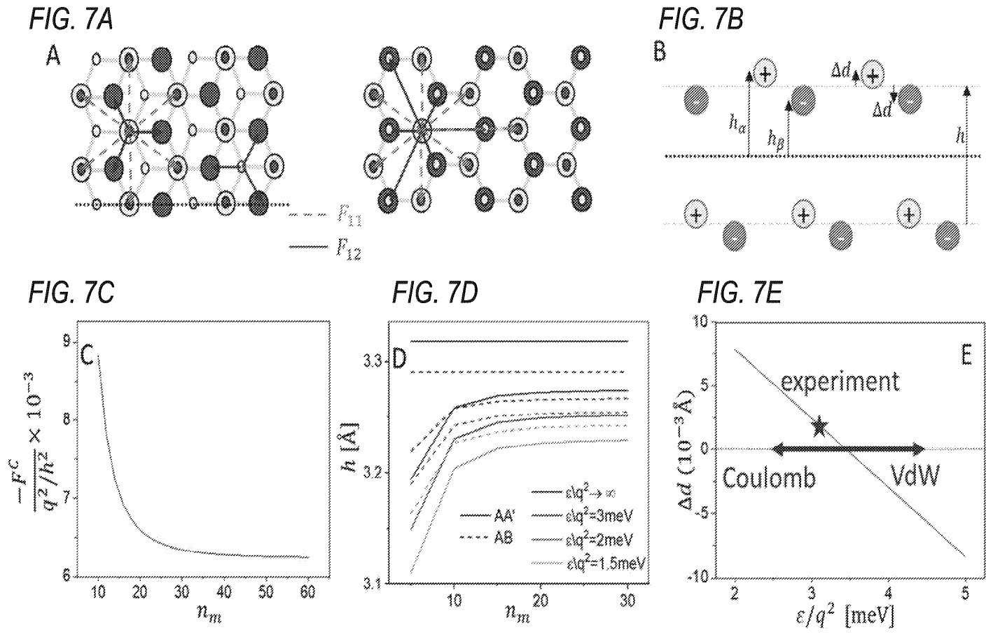

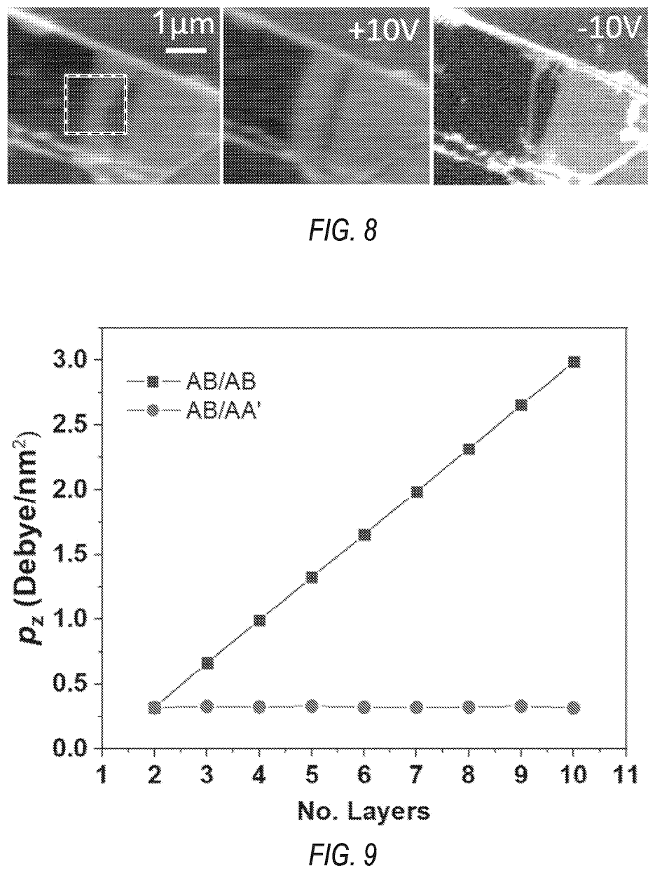

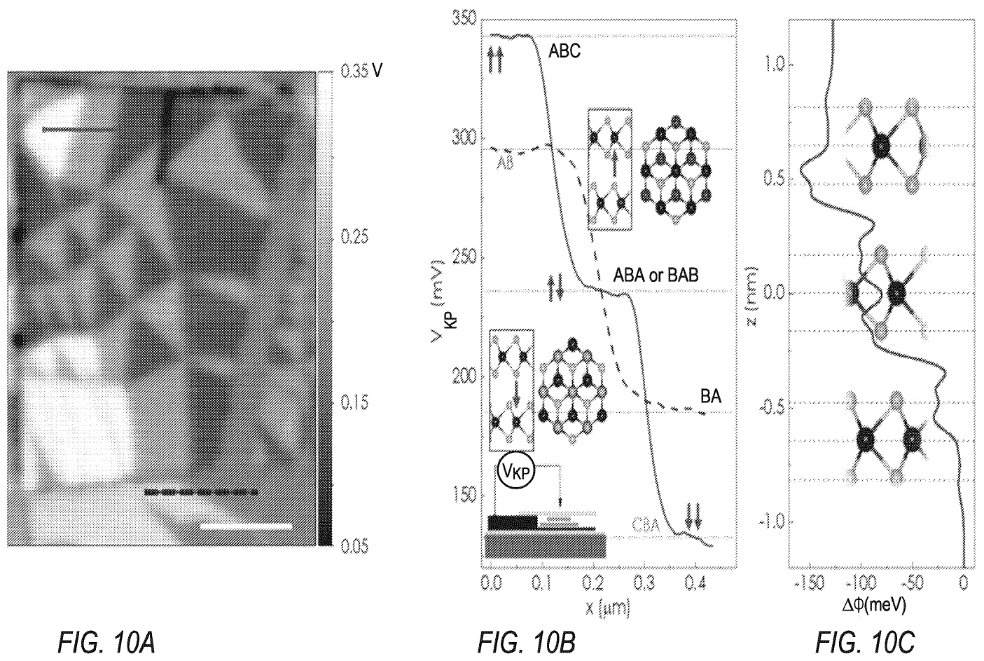

The zero-force condition yields the optimal interlayer distance h, marked in FIG. 7D by solid lines. As shown h decreases upon decreasing the Lenard-Jones energy scale ε with respect to the Coulomb energy.

We note that a reasonable approximation for F_{AA′}^{LJ}(h), for small R₀/h, consists of treating the particles as a uniform mass distribution, i.e. replacing the sum over \vec{R} by integration, yielding

$${F}_{continuu𝔪}^{LJ} ( h ) = {lim}_{{R}_{0} / h \to 0} {F}^{LJ} = ε \frac{32 π}{3 \sqrt{3} {R}_{0}^{2}} h ( \frac{{σ}^{12}}{{h}^{12}} - \frac{{σ}^{6}}{{h}^{6}} ) . \qquad ( S7 )$$

### Optimal Interlayer Spacing at the AB Stacking Mode

Now consider two h-BN layers at the AB stacking configuration. The corresponding interlayer force can be written as F_{AB}=F_{AB}^{LJ}+F_{AB}^{C}. The unit cell consists of two types of atomic sites, one type where atoms of the two layers reside atop of each other (eclipsed) and the other type where an atom of one layer resides atop a hexagon center of the other layer (hollow sites). Note that the Coulomb contribution of the hollow sites vanishes due to symmetry considerations. Hence, we only have the Coulomb contribution from the eclipsed atomic sites. Since the latter have the exact same configuration in the AA′ and AB stacking modes (see FIG. 7A) the overall Coulomb force contribution per atom in the AB stacking mode is half of that in the AA′ mode,

$${F}_{A B}^{C} = \frac{1}{2} {F}_{A {A}^{′}}^{C} .$$

For the VdW part, similar to the AA′ stacking case, the eclipsed atomic sites give F₁₁^{LJ}+F₁₂^{LJ} of Eq. S10, whereas the hollow atomic sites give 2F₁₂^{LJ} due to the unique symmetry of the AB stacked bilayer hexagonal lattice. Therefore, in total we obtain for the LJ force contribution per atom that

$${F}_{A B}^{L J} = \frac{{F}_{11}^{L J} + {F}_{12}^{L J}}{2} + \frac{2 {F}_{12}^{L J}}{2} = \frac{{F}_{11}^{L J}}{2} + \frac{3 {F}_{12}^{L J}}{2} .$$

The zero-force condition yields the optimal AB stacking interlayer distance, marked by the dashed gray line in FIG. 7D. Similar to the case of AA′ stacking mode, h decreases upon decreasing E/q². Note however, that while h (AA′)>h (AB) for large ε/q² the situation is inverted for

$$\frac{ε}{{q}^{2}} ≲$$

1.5 meV. Specifically, when q→0 our model corresponds to the case of graphite with optimal AB stacking mode.

### Relative Vertical Displacement

On top of the interlayer spacing, we now allow a small opposite motion of the hollow site (α) and eclipsed site (β) atoms: hₐ=h/2+Δd,h_{β}=h/2−Δd, (S8) as marked in FIG. S4B. We now analyze the total energy of the system as a function of Δd, via the Harmonic approximation

$$E ≅ const + {( \frac{dE}{d ( Δ d )} )}_{Δ d = 0} Δ d + \frac{1}{2} {( \frac{{d}^{2} E}{{d ( Δ d )}^{2}} )}_{Δ d = 0}$$

Δd² around Δd²=0. The assumption that Δd<<R₀ can be justified by the experimental estimate of Δd˜10⁻³ Å (see main text). Our simple model considered here, similar to an Einstein model for lattice vibrations, assumes that the Δd coordinates are independent Harmonic oscillators with spring constant

$${K}_{Δ d} = \frac{{d}^{2} E}{{d ( Δ d )}^{2}} .$$

Crucially, Δd=0 is not a minimum due to the reduced symmetry of the AB interface, with alternating eclipsed and hollow sites, which imposes a finite normal force (per atom) of:

$${F}_{Δ d} = - \frac{dE}{d ( Δ d )} = {F}_{Δ d}^{C} + {F}_{Δ d}^{LJ} , \qquad ( S 9 )$$

where F_{Δd}^{C} and F_{Δd}^{LJ} are defined as the relative displacement force contributions of the Coulomb and LJ terms. Note that F_{Δd} is the difference between the forces acting on the eclipsed versus the hollow sites.

Since, for Δd=0, hollow site atoms see a locally charge-neutral configuration on the other layer the Coulomb part of this linear force originates only from the eclipsed atomic sites. For the latter, the atom in the upper layer is attracted to the one residing exactly below it in the other layer. However, it is repelled by its next nearest neighbors in the other layer, and so on. When performing the entire lattice sum for the eclipsed site we obtain that the overall force is always attractive:

$${F}_{Δ d}^{C} = \frac{{F}_{11}^{C} ( h ) - {F}_{12}^{C} ( h )}{2} > 0 .$$

### (S10)

On the other hand, the LJ potential, which can be written as the difference between the hollow site (2F₁₂^{LJ}(h)) and the eclipsed site (F₁₁^{LJ}(h)+F₁₂^{LJ}(h)) contributions yields a repulsive force per atom near the equilibrium interlayer distance:

$${F}_{Δ d}^{L J} = \frac{2 {F}_{12}^{L J} ( h )}{2} - \frac{{F}_{11}^{L J} ( h ) + {F}_{12}^{L J} ( h )}{2} = \frac{{F}_{12}^{L J} ( h ) - {F}_{11}^{L J} ( h )}{2} < 0. \qquad ( S 11 )$$

This signifies that at the equilibrium interlayer distance, the eclipsed site contribution is more repulsive than that of the hollow site counterpart, mainly due to the fact that the eclipsed atoms are forced to reside within the steep Pauli repulsion wall side of their pairwise interaction.

Overall, from Eqs. S15 and S16 our crude estimate yields

$$Δ d ∼ \frac{{F}_{Δ d}}{{K}_{Δ d}} = \frac{( {F}_{11}^{C} ( h ) - {F}_{12}^{C} ( h ) ) + ( {F}_{12}^{L J} ( h ) - {F}_{11}^{L J} ( h ) )}{2 {K}_{Δ d}} . \qquad ( S12 )$$

K_{Δd} in Eq. (S17) can be evaluated from the model parameters (see next section). Nevertheless, for simplicity we take it to be equal to the corresponding out-of-plane force constant in graphite K_{Δd}˜5 N/m⁴⁴.

The resulting relative displacement is plotted in FIG. 7E versus ε/q². Crucially, it changes sign when

$${ε}_{eff} = \frac{ε}{{q}^{2}} ∼ 3.5 m eV .$$

The experimentally measured voltages indicate that Δd in AB stacked bilayer h-BN is of the order of 10⁻³ Å and our DFT calculations indicate that it is positive suggesting that

$$\frac{ε}{{q}^{2}} ∼ 3 meV$$

see FIG. 7E), similar to expected values. Notably, other layered materials, which possess different effective ε and or q values may show different quantitative and even qualitative polarization.

Finally, it should be noted that our simplistic classical approach is sufficiently flexible to allow to study additional effects such as the dependence on the number of layers as well as external perturbations like pressure or electric field, as well as an additional in-plane component of the polarization, which we leave for future work.

### Analytic Estimate of the Normal Spring Constant

To determine

$${K}_{Δ d} = \frac{{d}^{2} E}{{d ( Δ d )}^{2}} ,$$

we note that it has contributions from the interlayer LJ and Coulomb forces, as well as from the intra-layer forces. Its interlayer LJ contribution is obtained from the corresponding contribution to the energy

$${E}^{L J} ( Δ d ) = \frac{1}{2} [ {V}_{11}^{L J} ( h ) + {V}_{12}^{L J} ( h - 2 Δ d ) ] + \frac{1}{2} [ {V}_{12}^{L J} ( h ) + {V}_{12}^{L J} ( h + 2 Δ d ) ] .$$

The first (second) term represents the interaction of atoms at eclipsed (hollow) sites, and

$${V}_{11 ( 12 )}^{L J} ( h ) = 4 ε {\sum }_{{\vec{R}}_{11 ( 12 )}} ( \frac{{σ}^{12}}{{( {\vec{R}}_{11 ( 12 )}^{2} + {h}^{2} )}^{6}} - \frac{{σ}^{6}}{{( {\vec{R}}_{11 ( 12 )}^{2} + {h}^{2} )}^{3}} ) .$$

One can obtain a good approximation for the spring constant

$${( \frac{{d}^{2} E}{{d ( Δ d )}^{2}} )}_{Δ d = 0}$$

by replacing the sums Σ_{\vec{R}}_{₁₁₍₁₂₎} by integrals, as in F_{continuum}^{LJ}(h). This procedure yields

$${K}_{Δ d}^{LJ} = \frac{64 π}{\sqrt{3} {R}_{0}^{2}} ε . \qquad ( S13 )$$

For ε=3 meV this yields a spring constant of K_{Δd}^{LJ}=3 N/m. While additional contributions are expected from intra-layer interactions, as well as Coulombic inter-layer interactions, this value is comparable to the measured out-of-plane force constant in graphite K_{Δd}˜5 N/m⁴⁴. Since Eq. S13 captures the order of magnitude of K_{Δd}, we can use

$${K}_{Δ d} = \frac{64 π}{\sqrt{3} {R}_{0}^{2}} ε \cdot a ,$$

with a factor of order unity

$$a ∼ \frac{5}{3} ,$$

and obtain an approximate expression for the relative displacement, see Eq. (S17), fully in terms of our model's parameters,

$$Δ d ∼ \frac{{F}_{Δ d}}{{K}_{Δ d}} = \frac{\sqrt{3} {R}_{0}^{2}}{32 π} \frac{( {F}_{11}^{C} ( h ) - {F}_{12}^{C} ( h ) ) + ( {F}_{12}^{L J} ( h ) - {F}_{11}^{L J} ( h ) )}{4 ε} .$$

Having thus described several embodiments for practicing the inventive method, its advantages and objectives can be easily understood. Variations from the description above may and can be made by one skilled in the art without departing from the scope of the invention.

Accordingly, this invention is not to be limited by the embodiments as described, which are given by way of example only and not by way of limitation.

1-45. (canceled)

46. A process for inducing polarization in a stacked multilayered diatomic hexagonal material, the process comprising orienting any two stacked layers of a diatomic hexagonal multilayered material into a stacked parallel or a nearly parallel lattice orientation to induce internal interfacial electric field normal to the layers plane at an interface between the two stacked material layers.

47. The process according to claim 46, wherein the material is hexagonal-boron-nitride (h-BN) and/or transition-metal-dichalcogenides (TMD).

48. A process for inducing ferroelectricity to a polar diatomic hexagonal multilayered material, the process comprising applying a local electric field normal to a polar diatomic hexagonal multilayered material causing domain wall sliding, to thereby induce the ferroelectricity.

49. The process according to claim 48, comprising applying a local electric field by a biased electrode or tip above the hexagonal diatomic multilayered material surface.

50. The process according to claim 48, the process comprising applying a local electric field normal to a polar crystal of a diatomic hexagonal multilayered material, to thereby cause sliding of layers in said layered material relative to each other, to provide an array of permanent and switchable polarization domains in the crystal.

51. A process for manufacturing a ferroelectric crystal, the process comprising forming or obtaining a diatomic hexagonal multilayered material having a layered stacking configuration, wherein the material layers are stacked in a parallel or a nearly parallel lattice orientation to exhibit internal interfacial electric field normal to the layer plane of the crystal and applying electric field to said layered material to induce ferroelectric properties.

52. The process according to claim 48, wherein the polar diatomic hexagonal multilayered material has one or more same or different internal interfacial polar states.

53. The process according to claim 48, for inducing ferroelectric properties to h-BN crystal or TMD crystal.

54. A polar diatomic hexagonal multilayered material having ferroelectric properties for constructing an electronic or a photoelectric or an optical device.

55. A device implementing a polar diatomic hexagonal multilayered material having ferroelectric properties.

56. The device according to claim 55 implemented in an integrated circuit.

57. The device according to claim 56, wherein the integrated circuit is an integrated circuit memory.

58. The device according to claim 55, being selected from Random Access Memory (RAM), a flash-type memory, a ferroelectric field effect transistor, a CCD multiplexer read-out system, an integrated pyroelectric detector, an integrated surface acoustic wave device, a spatial light monitor, a microwave device, a ferroelectric tunnel junction, a ferroelectric transistor, a sensor and strain sensor.

59. A device implementing a diatomic hexagonal multilayered material, the material comprising two or more material layers oriented in a parallel or a nearly parallel lattice orientation to each other, exhibiting or having internal interfacial electric field normal to the layers plane, and having pre-determined multi-switch polarization states, each of said states being determined by summing up the number of interfaces having a polarization component pointing in one direction normal to the multilayer plane, minus the number of interfaces with a polarization component pointing in the opposite direction.

60. The device according to claim 59, wherein the material is h-BN or TMD.

61. A polarization state changing device comprising at least two pre-determined multi-switch polarization states, wherein each of the at least two polarization states comprise a difference between interfaces having a polarization pointing in a first direction normal to the multilayer plane and interfaces having a polarization pointing in a second direction that is opposite the first direction; and wherein the switch includes two or more layers of selected from the group consisting of hexagonal boron nitride (h-BN) and transition-metal-dichalcogenides (TMDs), wherein the two separate pieces are configured in a stack.

62. The device according to claim 61, wherein the switch occurs by either applying an external electric field or a mechanical stimulation to shift the domain wall and locally switch the polarization.

63. The device according to claim 61, wherein the thickness of the multilayer does not affect the polarization state.

64. The device according to claim 48, wherein the device is one of a Random Access Memory (RAM), a flash-type memory, a ferroelectric field effect transistor, a CCD multiplexer read-out system, an integrated pyroelectric detector, an integrated surface acoustic wave device, a spatial light monitor, a microwave device, a ferroelectric tunnel junction, a ferroelectric transistor, a sensor, and a strain sensor.

65. The device according to claim 48, wherein the difference is determined by summing the interfaces having a polarization component pointing in the first direction and subtracting the interfaces having a polarization component pointing in the second direction.
